(19) United States
(12) Patent Application Publication
(10) Pub. No.: US 2007/0296604 A1
(43) Pub. Date: Dec. 27, 2007

(54) Remote controller

(75) Inventor: Tomoyuki Koyata, Kanagawa (JP)

Correspondence Address: DRINKER BIDDLE & REATH LLP, Suite 1100, 1500 K Street, N.W., Washington, DC, 20005-1209, US

(73) Assignee: PIONEER CORPORATION

(21) Appl. No.: 11/802,772

(22) Filed: May 24, 2007

(30) Foreign Application Priority Data
May 25, 2006 (JP) P2006-144834

(51) Int. Cl. G05B 19/02; G06K 9/00; H03M 11/00

(52) U.S. Cl. 340/825.22; 341/22; 348/207.99; 382/100

(57) ABSTRACT

A remote controller includes: an image taking unit that takes in image data of devices by photographing; a storing unit that stores the image data and registers the devices; a setting unit that sets a control code for each of the registered devices; an image recognizing unit that recognizes a device for operating by image recognition; a searching unit that identifies the recognized device from the registered devices; and a switching unit that switches the control code and an allotment of operation keys for the identified device.

### CROSS-REFERENCE TO RELATED APPLICATIONS

This application is based on and claims the benefit of priority from the prior Japanese Patent Application No. 2006-144834, filed on May 25, 2006; the entire contents of which are incorporated herein by reference.

### BACKGROUND

1. Technical Field

The present invention relates to a remote controller for remote controlling a plurality of devices to be controlled.

2. Related Art

A remote controller has been widely employed in common houses for the purpose of remote controlling a device to be controlled such as a television receiver, a video deck, a CD player, an air conditioner, etc. The remote controller used for the device issues a signal which contains a control code for transmitting operation to the device mainly by infrared, thereby enabling the device to perform the operation corresponding to the control code.

In the remote controller of this type, it has been necessary to issue a specific control code corresponding to each of the devices, namely, the television receiver, air conditioner, etc. For example, the remote controller for the television receiver cannot operate the air conditioner.

Similarly, the remote controller for the air conditioner cannot control operation of the television receiver. For this reason, it has been necessary to prepare a plurality of remote controllers exclusive to the respective devices, and there has been such disadvantage that storage and maintenance of these remote controllers have been annoying.

Although some remote controllers for a DVD recorder, a video deck and soon which are connected to television receivers for recording images can conduct channel selection and volume control of other television receivers of the same or other manufacturers, specific control exclusive to an electronic device which is intended for utterly different use has not been considered. For example, temperature setting of the air conditioner cannot be remote controlled with these remote controllers.

On the other hand, there has been a remote controller called as a “learning remote controller” of a type that a plurality of remote controller functions are concentrated in a single remote controller. This type of remote controller is so constructed that control codes for a plurality of devices to be controlled have been registered beforehand, or control codes outputted from a plurality of devices have been learned, whereby a plurality of the devices can be respectively controlled to their determined functional modes by the single remote controller.

Moreover, there has been proposed a remote controller which can ensure substantially same operability as the remote controller exclusive to the device to be controlled, by storing, in a storage section of the device, image data for showing a picture of operating buttons in the same arrangement as on the remote controller exclusive to this device through a touch panel, as shown in JP-A-2003-23680.

### SUMMARY

With the conventional learning remote controller and the remote controller disclosed in JP-A-2003-23680, it has been possible to control a plurality of devices by a single remote controller, by learning the control codes of the devices or by obtaining the control codes and the data of arrangement of the operating buttons from the devices. However, as for switching between the devices, a user has been required to select the desired device, by operating keys of the remote controller.

Therefore, in order to switch a number of devices to be controlled, it has been necessary to provide many switch buttons or to give a plurality of modes to a single key. This requires such complicated operation that the user must judge a type of the device to be controlled, search a switch button and a switch mode for switching over to the relevant device, and then, operate the switch button and the switch mode. Besides, selection of the desired device has not been easy. Moreover, because it has been difficult to judge whether or not the desired device has been correctly selected, particularly children and aged users have had difficulties in handling this remote controller.

It is one of the objects of the invention to provide a remote controller capable of controlling a plurality of devices to be controlled, in which switch over to the device which a user desires to operate can be simply and automatically performed.

According to an aspect of the invention, there is provided a remote controller including; an image taking unit that takes in image data of devices by photographing; a storing unit that stores the image data and registers the devices; a setting unit that sets a control code for each of the registered devices; an image recognizing unit that recognizes a device for operating by image recognition; a searching unit that identifies the recognized device from the registered devices; and a switching unit that switches the control code and an allotment of operation keys for the identified device.

### BRIEF DESCRIPTION OF THE DRAWINGS

FIG. 1 is a plan view and a side view showing an outer appearance of a remote controller in an embodiment according to the invention;

FIG. 2 is a table showing allotments to operation keys in the remote controller in the embodiment according to the invention;

FIG. 3 is a block diagram showing functions of the remote controller in the embodiment according to the invention;

FIG. 4 is a flow chart showing steps for registering a device to be controlled in the remote controller in the embodiment according to the invention; and

FIG. 5 is a flow chart showing steps for controlling the device to be controlled by the remote controller in the embodiment according to the invention.

### DESCRIPTION OF THE EMBODIMENTS

An embodiment of the invention will be described hereunder.

The remote controller in the embodiment according to the invention is characterized by including: an image taking unit that takes in image data of devices by photographing; a storing unit that stores the image data and registers the devices; a setting unit that sets a control code for each of the registered devices; an image recognizing unit that recognizes a device for operating by image recognition; a searching unit that identifies the recognized device from the registered devices; and a switching unit that switches the control code and an allotment of operation keys for the identified device.

The remote controller in this embodiment can control the device to be controlled which the user desires to operate, by automatically switching the control code and its allotment to the operation key, with a simple operation that the remote control is directed to the desired device.

A specific embodiment of the remote controller according to the invention will be described in detail, referring to the drawings.

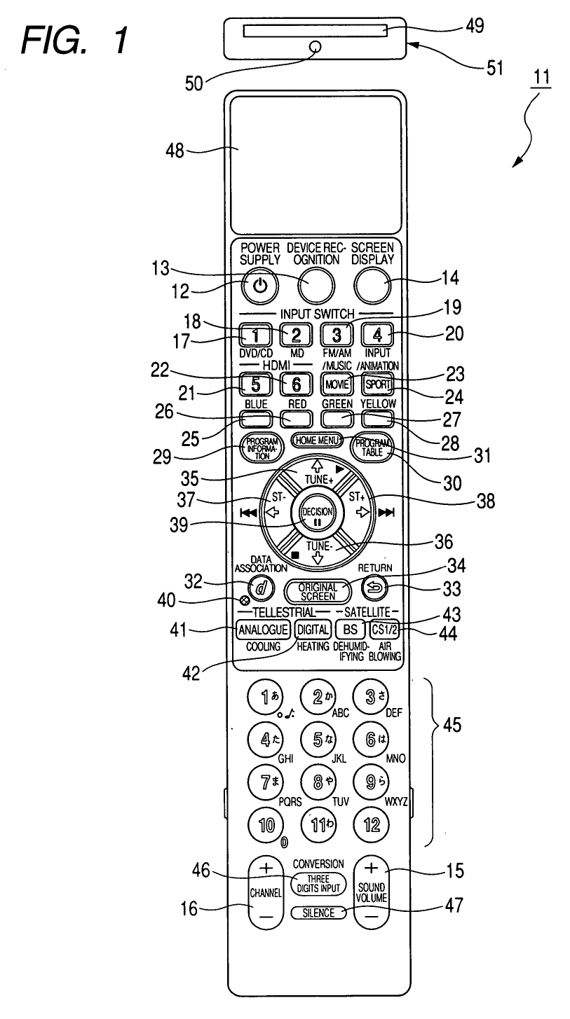

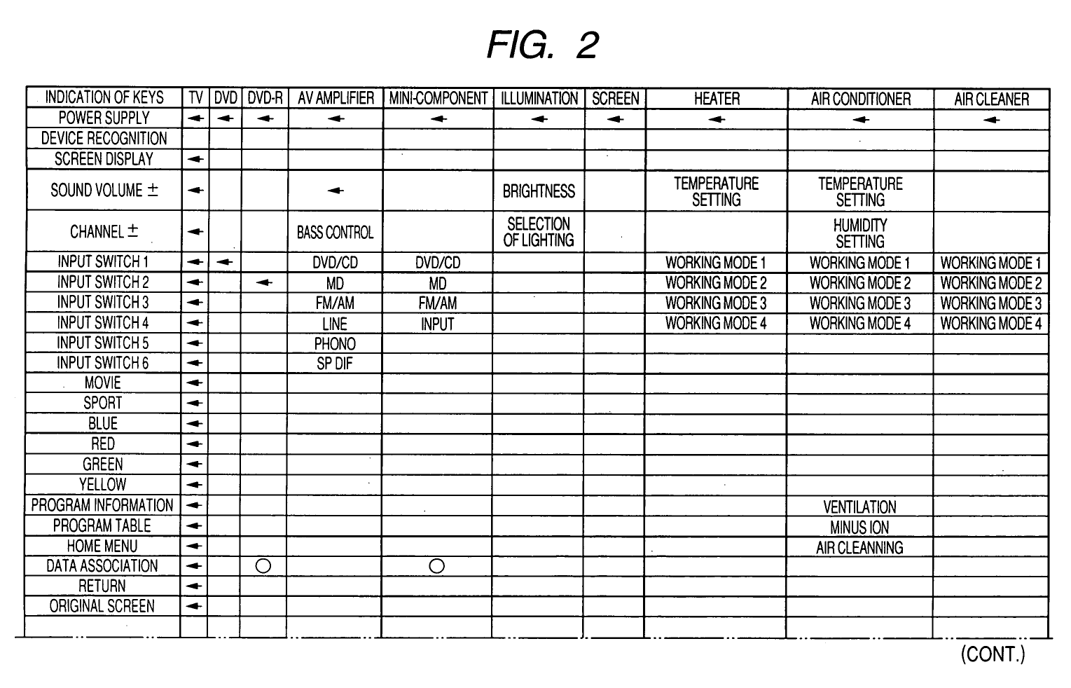

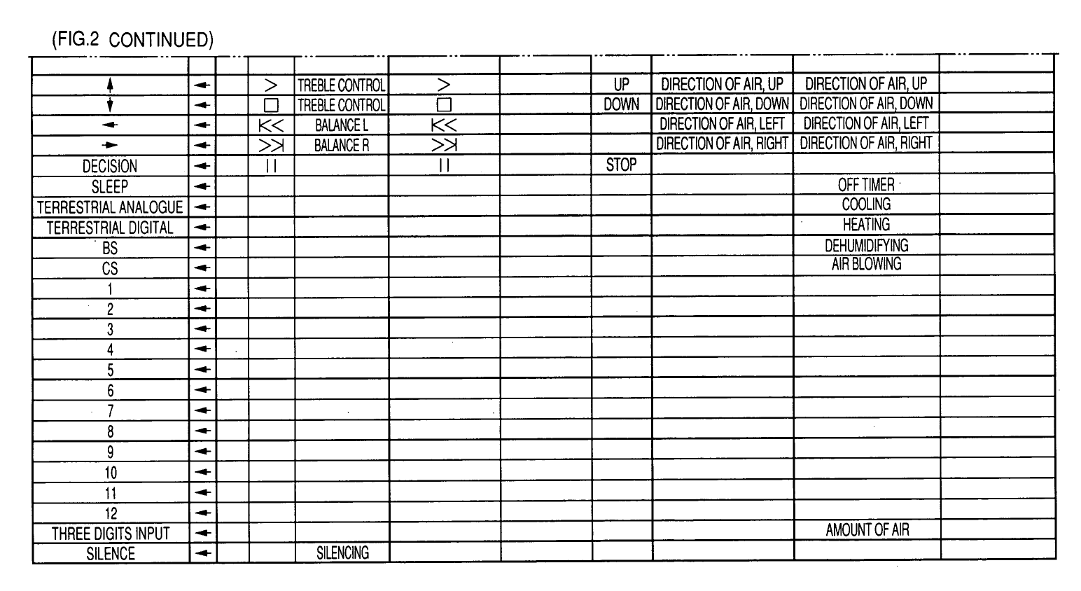

FIG. 1 is a plan view showing a surface of the remote controller in the embodiment according to the invention and a side view of a front end part of the remote controller, and FIG. 2 is a table showing allotments to the operation keys.

On the surface of a remote controller 11, there are arranged a power supply key 12, a device recognition key 13, a screen display key 14, a sound volume key 15, a channel key 16, input switch keys 17 to 22, a movie key 23, a sport key 24, operation keys 25 to 28 respectively for blue, red, green, and yellow, a program information key. 29, a program table key 30, a home menu key 31, a data association key 32, a return key 33, an original screen key 34, operation keys 35 to 38 of ↑, ↓, ←, →, a decision key 39, a SLEEP key 40, a terrestrial analogue key 41, a terrestrial digital key 42, a BS key 43, a CS key 44, channel keys 45 for channels 1 to 12, a three digits input key 46, a silence key 47. Determined operation modes respectively for the devices to be controlled are allotted to these operation keys 12 to 47, as shown in the table of the operation key allotment in FIG. 2.

The power supply key 12 serves for energizing the power supply of the device to be controlled.

The device recognition key 13 serves for taking an image of the device to be controlled.

The screen display key 14 serves for displaying the image which has been taken.

The sound volume key 15 serves for controlling sound volume of television broadcasting and an AV amplifier, and also serves for controlling brightness of illumination and for setting temperature of a heater and an air conditioner.

The channel number change key 16 serves for selecting channels of the television broadcasting and a DVD, for controlling bass of the AV amplifier, for selecting the illumination to be lit, and for setting the temperature of the air conditioner.

The input switch key 17 serves for switching DVD/CD input of the AV amplifier, for switching DVD/CD input of a mini-component, and for setting working mode 1 of the heater, air conditioner and an air cleaner.

The input switch key 18 serves for switching MD input of the AV amplifier and the mini-component, and also serves for setting working mode 2 of the heater, air conditioner and air cleaner. The input switch key l9 serves for switching FM/AM input of the AV amplifier and mini-component, and also serves for setting working mode 3 of the heater, air conditioner and air cleaner.

The input switch key 20 serves for switching LINE input of the AV amplifier, and for setting INPUT of the mini-component, and also serves for setting working mode 4 of the heater, air conditioner and air cleaner.

The input switch key 21 serves for switching PHONO input of the AV amplifier.

The input switch key 22 serves for switching SPDIF input of the AV amplifier.

The movie key 23 serves for setting movie genre, the sport key 24 serves for setting sport genre, the operation keys 25 to 28 of blue, red, green and yellow serve for commands on the screen, the program information key 29 serves for displaying or not displaying detailed information of the program, and also serves for setting ventilation of the air conditioner, and the program table key 30 serves for displaying or not displaying the program table, and also serves for generating minus ion in the air conditioner.

The home menu key 31 serves for setting air cleaning in the air conditioner, the data association key 32 serves for recording pictures and sounds in a DVD-R and the mini-component, the return key 33 serves for canceling a menu which has been set, returning it to a prior menu, or to a higher menu, the original screen key 34 serves for returning the screen to the original one, the operation keys 35 to 38 of ↑, ↓, ←, → serve for controlling treble of the AV amplifier, sound balance between right and left, reproducing, stopping, fast forwarding, and fast rewinding of the DVD-R and the mini-component, up and down of the screen, and for controlling direction of air of the heater and air conditioner.

The decision key 39 serves for temporarily stopping the DVD-R and the mini-component, and for stopping up and down of the screen, the SLEEP key serves for an off timer of the air conditioner. The terrestrial analogue key 41, the terrestrial digital key 42, the BS key 43, the CS key 44 also serve for cooling, heating, dehumidifying, and blowing of the air conditioner, respectively. The channel keys 45 serve for inputting channel numbers, values and letters, and the three digits input key serves for setting volume of air of the air conditioner. The silence key 47 serves for silencing the AV amplifier. Numeral 48 designates a display part formed of liquid crystal or an organic EL display.

Numeral 51 designates a side face of the front end part of the remote controller 11. An infrared transmitting and receiving part 49 and a lens 50 which supplies an image to an image taking section 62 are provided on this side face.

It is to be noted that position of the lens 50 is not limited to the side face of the front end part, but may be a back face of the remote controller 11, for example, provided that the lens 50 is mounted at a position opposed to the device to be controlled, when the user take a picture of the device by grasping the remote controller 11.

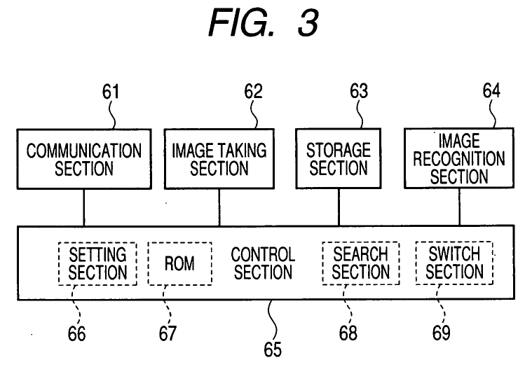

FIG. 3 is a block diagram showing functions of the remote controller in the embodiment according to the invention. As shown in FIG. 3, the remote controller 11 in this embodiment includes a communication section (a communicating unit) 61, an image taking section (an image taking unit) 62, a storage section (a storing unit) 63, an image recognition section (an image recognizing unit) 64, and a control section (a control unit) 65.

The communication section 61 functions to send a control code by an infrared signal, for example, to a device to be controlled (not shown). An infrared light emitting diode, for example, is provided in this communication section 61, while an infrared light receiving element is provided in the device to be controlled. It is also possible to use various types of transmitting and receiving elements such as an element for transmitting and receiving electric waves, or an element for transmitting and receiving ultrasonic waves, instead of the infrared light emitting diode and the infrared light receiving element.

The image taking section 62 includes an image taking element such as a CCD for taking an image of the device to be controlled which has been supplied through the lens 50. The storage section 63 functions to store the image data which have been obtained from the image taking section 62, and also functions to store and register the control codes which have been set corresponding to the image data.

The image recognition section 64 functions to identify the type of the device to be controlled, by recognizing the image of the device which has been taken in the image taking section 62, and by judging whether or not this image corresponds to either of a plurality of the devices which have been already registered in the storage section 63.

The control section 65 has a function of switching the control code to the control code corresponding to the identified device (a switching unit), and functions to control operations of the communication section 61, the image taking section 62, the storage section 63, and the image recognition section 64.

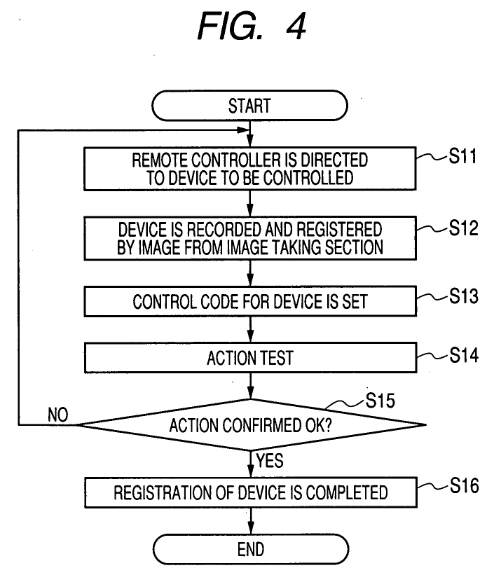

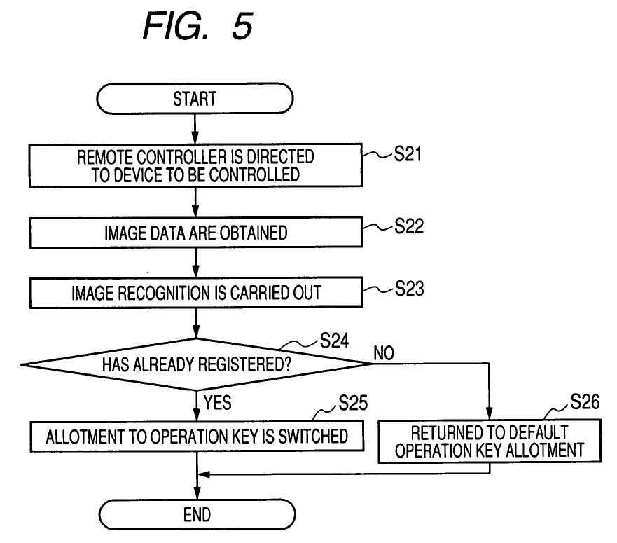

Then, operation of the remote controller in this embodiment will be described referring to flow charts as shown in FIGS. 4 and 5.

It is possible to register a plurality of the devices to be controlled in the remote controller 11 in this embodiment. Steps for registration will be described. FIG. 4 is a flow chart showing the steps for registering the devices to be controlled in the remote controller in this embodiment.

As a first step, the user will take the remote controller 11 by hand so as to direct the front end part 51 of the remote controller 11 as shown in FIG. 1 to the device to be controlled (a step S11). The user will operate the device recognition input key 13, while the remote controller 11 is directed to the device, whereby image taking operation will be started in the image taking section 62, and the image data of the device will be taken into the image taking section 62.

In case where the devices to be controlled are installed close to each other, or in case where a plurality of the devices are mounted on a same rack, it is possible to confirm a monitor image shown on the display part 48 of the remote controller 11, and to take in the image data by selecting a range in a manner of encircling an outline of the device to be registered with a frame on the screen.

The image data which has been taken into the image taking section 62 will be stored in the storage section 63, and registered as the image data for identifying the device, which will be described below (a step S12). Registration of the image data will be respectively conducted for a plurality of the devices which the user desires to operate.

In case where the remote controller 11 belongs to a particular device when the device is sold (the remote controller for a television receiver, for example), the image data of the essential device (the television receiver or a recorder of the same manufacturer, for example) have been already taken and registered in the remote controller. The invention can be applied to this case too.

The setting section 66 (a setting unit) in the control section 65 will set a control code for the device which has been registered (a step S13). Because the control codes corresponding to the dominant manufacturers and types of the devices have been already preset in a ROM 67 in the control section 65, the control code for the relevant manufacturer and type of the device corresponding to the image data will be selected and set. In case where the registered device is of a manufacturer or a type whose control code has not been preset in the ROM 67 in the control section 65, the remote controller 11 will receive a signal of the control code issued from a remote controller exclusive to the device, and will set the control code by learning this signal.

Moreover, the remote controller 11 may be so constructed that out of the operation keys allotted to the registered devices, only one operation key to be used emits a light, and further, the emitted lights are set to have respectively different colors. In this manner, it is possible to clearly show which device has been recognized, when the remote controller 11 is directed to the device for use. Further, operability will be enhanced, because only the key which is effective for the device to be operated emits the light. Still further, it is also possible to illuminate the letters and symbols which explain functions of the operation keys.

As a specific method for emitting the lights and varying colors of the lights as described above, a plurality of LEDs of three types which emit the lights having three colors, red (R), green (G), and blue (B) may be provided in a single operation key, and duty ratio between light emission actuating signals may be controlled thereby to vary amounts of the emitted lights for respective colors. In this manner, various kinds of colors can be realized.

It is to be noted that order of the above described step S12 and step S13 may be reversed. Specifically, the image of the device to be controlled may be taken in and registered, after the type of the device (the manufacturer or the type of device) has been determined and the control code has been set.

Then, a test for confirming whether or not the device to be controlled has been accurately registered will be carried out (a step S14). In order to carry out this test, after the control code has been set in the step S13 for example, the remote controller 11 will be once directed to the other direction, and then, the front end part 51 of the remote controller 11 will be again directed to the device to be controlled. On this occasion, it will be confirmed whether or not the key of the remote controller 11 emits a light, and whether or not the color of the emitted light matches the color which has been set. In addition, the functions of the device will be arbitrarily put into effect by operating the key, thereby to confirm their operations. Then, from the results of these tests, whether or not the device has been accurately registered will be judged (a step S15).

In case where it is judged that the device has been accurately registered (YES), the registration of the device to be controlled into the remote controller 11 will be finished (a step S16).

On the other hand, in case where it is judged that the device has not been accurately registered (NO), an error message may be shown on the display part 48, and the registration will be restarted from the step S11.

Now, a method of controlling the device by the remote controller in the embodiment according to the invention will be described. FIG. 5 is a flow chart showing steps for controlling the device by the remote controller in this embodiment.

After a plurality of the devices to be controlled have been registered according to the aforesaid registration steps as shown in FIG. 4, it will be possible to respectively control the devices which have been registered in this remote controller 11.

As a first step, the user will direct the front end part 51 of the remote controller to the device which he desires to control (a step S21). For example, when the user desires to control the television receiver, he will direct the front end part 51 to the television receiver.

Further, it is required that battery consumption of the remote controller 11 may be depressed to the least. Therefore, it would be preferable that the remote controller 11 is usually in a sleeping mode in which almost no battery consumption is observed, and the sleeping mode may be released only when the remote controller is used. For this purpose, a sensor may be provided on the remote controller 11 to judge whether or not the remote controller is in use. For example, touch sensors may be provided on both side faces of the remote controller 11 (electrodes may be provided on both the side faces so that the user may touch the two electrodes simultaneously for detection), or a sensor may be provided on a bottom part so that it can be detected that the remote controller 11 which had been placed on a table has been taken up.

It is also possible to return the remote controller 11 to the sleeping mode, in case where any key operation by the user is not effected for a certain time, or in case where it is detected that the remote controller has been placed on the table.

Then, the device recognition key 13 will be operated in a state where the remote controller 11 is directed to the device to be controlled, thereby to generate a trigger for taking the image. With this trigger, the image data will be taken into the image taking section 62 (a step S22).

It is also possible for the image taking section 62 to automatically take the image data always or at intervals of a certain period, or by some action as a trigger, without operating the device recognition key 13.

The image data of the device which have been taken will be inputted into the image recognition section 64, and the image recognition will be carried out (a step S23).

Further, the image data will be compared with the image data which have been stored and registered in the storage section 63, and a search section 68 (a searching unit) in the control section 66 will search the matching image data to identify the device, whereby whether or not the device which the user desires to control has been already registered in the storage section 63 will be confirmed (a step S24).

In case where the control section 65 has confirmed that the device which the user desires to control had been already registered (YES), the control code of the remote controller 11 and its allotment to the operation key will be switched by a switching section (a switching unit) 69 (a step S25).

On the other hand, in case where the device which the user desires to control has not been already registered (NO), the step will be returned to a default device (for example, the television receiver) (a step S26).

As described above, each of the operation keys of the remote controller 11 can be allotted to the operation key corresponding to the device which the user desires to control. Accordingly, by pressing the key having a desired function after it has been switched, the user will be able to conduct desired control of the device.

Specifically, in case where the device to be controlled is the television receiver, it will be possible to conduct selection of channels, control of sound volume, control of image quality and so on, by operating the various keys provided on the remote controller 11 such as the sound volume key 15, the channel number changing key 16, the channel keys 45, etc.

Moreover, it is possible to display a name of the matched device on the display part 48 of the remote controller 11 on which the allotment to the operation key has been switched.

In case where the operation key is so designed as to emit a light, the color of the emitted light of the operation key may be switched to the color corresponding to the matched device. In addition, it is also possible to illuminate the letters and symbols for explaining the functions of the operation keys. Further, in case where a sound guide function is provided, it is possible to output contents of the operation by sound, when the operation key is operated (for example, “sound volume will be raised”, “recording will be started”, “reproduction will be started”, etc.).

As described above, recognition of the device to be controlled, switch of the control code and its allotment to the operation key can be performed inside the remote controller 11. As the results, the user can control the desired device, by automatically switching the control code to the control code of the device to be controlled, with such a simple work that the remote controller is directed to the device which he desires to operate.

Therefore, the user will be released from such annoying work that he must judge the type of the device to be controlled in a switching process of the device, search the switch button for switching to the relevant device, and then, operate this button.

Further, instead of recognizing the device to be controlled by the remote controller 11, it is possible to recognize the device by characteristic features on a part of the device or by letters or symbols attached to the device.

It is also possible to provide a manual mode switching key on the remote controller, and to operate a selection key of the device, in case of manual mode, for the purpose of switching the device to be controlled. Further, a lock key may be provided on the remote controller so that switch of the control code and its allotment to the operation key may be prohibited in a locked state.

Moreover, the image data for identifying the device to be controlled is not necessarily of the image of the device itself, in case where electric wave having low directivity but not the infrared signal having high directivity is used as the communicating unit of the remote controller. For example, it is possible to recognize an amplifier from the image data of a speaker. Accordingly, when the speaker has been recognized by directing the front end part 51 of the remote controller to the speaker, sound volume and so on of the amplifier can be controlled in this state.

As fully described above referring to the embodiment, the remote controller in this embodiment includes the image taking section 62 which takes in the image data of the device to be controlled, by photographing the device, the storage section 63 which stores the image data and registers the device, the setting section 66 which sets the control code for the registered device, the image recognition section 64 which recognizes the image of the device which the user desires to operate, the search section 68 which identifies the recognized device out of the devices which have been registered, and the switch section 69 which switches the control code and its allotment to the operation key for the identified device. Accordingly, it is possible to control the desired device, by automatically switching the control code and its allotment to the operation key for the device, with such a simple work that the remote controller is directed to the device which the user desires to operate.

Therefore, even a child and an aged man, for example, can easily conduct a changeover of the device to be controlled.

What is claimed is:

1. A remote controller comprising:
an image taking unit that takes in image data of devices by photographing;
a storing unit that stores the image data and registers the devices;
a setting unit that sets a control code for each of the registered devices;
an image recognizing unit that recognizes a device for operating by image recognition;
a searching unit that identifies the recognized device from the registered devices; and
a switching unit that switches the control code and an allotment of operation keys for the identified device.

2. The remote controller according to claim 1, wherein
the image taking unit includes a lens, and the image taking unit takes in the image through the lens.

3. The remote controller according to claim 1, wherein
the control code is preset.

4. The remote controller according to claims 1, wherein
the remote controller receives a signal of a control code issued from a remote controller exclusive to each of the devices.

5. The remote controller according to claims 1, wherein:
the operation keys, which are allotted to the identified device, emit light; and
the emitted light is set to have different colors with respect to each of the devices.

6. The remote controller according to claim 1, wherein
the image taking unit takes in the image by a trigger as a cue.

7. A remote controller according to claim 6, wherein
the trigger occurs when a predetermined key included in the operation keys is operated.

8. A remote controller according to claim 6, wherein
the trigger automatically occurs at intervals of a certain period.

9. A remote controller according to claim 1, wherein when a device is not identified by the searching unit, a control code that is previously determined and an operation key with respect to the control code are allotted to the device.
